(19) United States
(12) Patent Application Publication
(10) Pub. No.: US 2024/0296269 A1
(43) Pub. Date: Sep. 5, 2024

(54) MODELING OF FOUR-STATE-AWARE MEMORIES IN AN EMULATION SYSTEM

(71) Applicant: Cadence Design Systems, Inc., San Jose, CA (US)

(72) Inventors: Mitchell G. Poplack, San Jose, CA (US); Bhoumik Shah, Newark, CA (US); Jennifer Lee, San Jose, CA (US)

(21) Appl. No.: 18/178,463

(22) Filed: Mar. 3, 2023

(51) Int. Cl. G06F 30/3308

(52) U.S. Cl. CPC G06F 30/3308

(57) ABSTRACT

The systems and methods described herein include emulators that implement wrappers comprising instrumentation logic for the emulator components (e.g., memories) to perform certain memory-related functions. These functions allow the physical binary memories of the emulator to behave as a ternary memory. The memory wrappers include instrumentation logic around logic of the physical binary memories. In some cases, embodiments generate the wrappers for the user memory, rather than performing conventional synthesis functions for user-design memories. The inputs include the user ternary RTL, as well as additional potential inputs for pre-compiler control. The wrappers instantiate the operations, such as MPRs or MPWs, and create the ternary-memory support logic to, for example, prevent unknown-value writes and to output unknown values X for unknown-value reads.

### TECHNICAL FIELD

This application is generally directed towards emulation systems and more specifically towards emulation system memories that support representation of three-state signals in emulators supporting four potential logic states.

### BACKGROUND

Modern semiconductor based integrated circuits (ICs) are incredibly complex and contain millions of circuit devices, such as transistors, and millions of interconnections between the circuit devices. Designing such complex circuits cannot be accomplished manually, and circuit designers use computer based Electronic Design Automation (EDA) tools for synthesis, debugging, and functional verification of the ICs.

A significant function of EDA tools is emulation of a user logical system (e.g., an IC design) to perform pre-silicon functional verification, firmware and software development, and post-silicon debug. To achieve this, a typical processor-based emulation system comprises several Application Specific Integrated Circuits (ASICs) all working together to execute a program generated by an emulation compiler generated from the user's IC design. The compiled program models a design under test (DUT) that is a logical representation of the user's IC design running on the emulation system.

Conventional emulation systems are limited to supporting two-state known logic, handling only ones (1) and zeros (0). More specifically, the logic signals computed, detected, and stored within conventional emulation may represent only either “0” or “1.” Some recent developments in conventional emulation systems introduced processors and logic devices capable of handling four-state logic, including “0,” “1,” unknown (“X”), and undriven (“Z”). In these improved conventional emulation systems, an IC design is compiled into an IC representation file (e.g., netlist) for execution by components of the emulator, where IC representation file includes three possible logical values (0, 1, X) for the logic gates. However, these recent conventional emulation systems still have limitations in modeling memory components of the user's design and limitations in emulating the DUT, where the emulators and the DUT may be limited to only physical binary memories.

### SUMMARY

Conventional emulation systems include logic gates and other functional components for performing the DUT. The memory components of the conventional emulators cannot handle three potential states. What is needed is an emulation system having software and hardware capable of emulating unknown logic states in the functional components and the storage memory. What is needed is an emulator capable of emulating ternary memories.

Disclosed herein are systems and methods capable of addressing the above-described shortcomings and may also provide any number of additional or alternative benefits and advantages. Embodiments include IC design and verification system, including hardware and software components of an emulator. The systems and methods described herein include an emulation system that generates and implements emulator instrumentation logic for modeling device components and functions of a user's circuit design, which operates with an unknown logic state (X). A netlist of the circuit design includes logic for emulator processors and physical memories to model the circuit design with three logical states (0, 1, X). The complier (or other software program) compiles logic of a netlist for a circuit design, which is then loaded into instruction memories of the emulation processors. In some cases, the netlist includes one or more ternary memories and the complier (or other software) generates additional instrumentation logic added to the netlist of the DUT, where the emulator implements certain instrumentation logic around emulator components (sometimes referred to as “wrappers”). For instance, a wrapper includes instrumentation logic that enables the emulator's binary physical memory components to function in a manner that models a ternary memory. The memory wrappers include emulator logic adding support logic to the logic compiled from the user's design logic or netlist. The compiler adds logic of the wrapper into the logic of the netlist around the logic of a particular memory, for example, memory port reads (MPRs) or memory port writes (MPWs) to add these features. The compiler may merge the logic of the wrapper into the netlist's logic by, for example, injecting the logic of the wrapper around the logic of the memory and/or by replacing certain logic of the memory. In some cases, the compiler generates the wrappers for the user memory, rather than performing conventional memory synthesis that would generate instances of a memory or memory functions in the instrumentation logic of the netlist. The inputs include the user ternary RTL, as well as additional potential inputs for pre-compiler control. The wrappers instantiate the operations, such as MPRs or MPWs, and create the ternary-memory support logic to prevent unknown-value writes and to output unknown values X for unknown-value reads.

In an embodiment, an emulation system comprising emulator hardware for emulating a circuit design, including one or more emulation processors for modeling user design circuits of a netlist for the circuit design, and one or more physical binary memories for modeling user design memories of the netlist; and a computing processor configured to: identify, in the user design memories of the netlist, a user ternary memory to be modeled using a physical binary memory; and instantiate a wrapper for modeling the user ternary memory, the wrapper includes instrumentation logic configured to perform one or more logical transformations of a ternary interface signal to model the user ternary memory, wherein the user ternary memory is modeled using a combination of the instrumentation logic of the wrapper and a portion of the netlist for the physical binary memory.

In another embodiment, an emulation system comprises emulator hardware for emulating a circuit design that operates with an unknown logic state, including one or more emulation processors for modeling user design circuits of a netlist for the circuit design, and a plurality of physical binary memories for modeling user design memories of the netlist; and a computing processor configured to: identify, in the user design memories of the netlist, a user ternary memory to be modeled using a physical binary memory; and instantiate a wrapper for modeling the user ternary memory, the wrapper includes instrumentation logic configured to perform a memory corruption function, wherein the user ternary memory is modeled using a combination of the instrumentation logic of the wrapper and a portion of the netlist for the physical binary memory.

It is to be understood that both the foregoing general description and the following detailed description are exemplary and explanatory and are intended to provide further explanation of the invention as claimed.

### BRIEF DESCRIPTION OF THE DRAWINGS

The present disclosure can be better understood by referring to the following figures. The components in the figures are not necessarily to scale, emphasis instead being placed upon illustrating the principles of the disclosure. In the figures, reference numerals designate corresponding parts throughout the different views.

FIG. 1 shows components of a system for emulation that supports representation of four-state signals or logic states, according to an embodiment.

FIG. 2A shows components of a system for performing emulation processes, including components within an emulation chip of the emulation system, according to an embodiment.

FIG. 2B depicts a logical representation of a user-design ternary memory wrapper including instrumentation logic wrapped around physical hardware components.

FIG. 3 shows operations of a method for an emulation system having physical binary memory components to emulate and model an IC design that operates with unknown logic states and ternary memory functionality, according to an embodiment.

### DETAILED DESCRIPTION

Reference will now be made to the illustrative embodiments illustrated in the drawings, and specific language will be used here to describe the same. It will nevertheless be understood that no limitation of the scope of the invention is thereby intended. Alterations and further modifications of the inventive features illustrated here, and additional applications of the principles of the inventions as illustrated here, which would occur to a person skilled in the relevant art and having possession of this disclosure, are to be considered within the scope of the invention.

Embodiments described herein include systems and methods for IC design and verification, including emulation systems for emulating three-state or four-state logic values in emulation processors. The four logic values include a known logic value of 0, a known logic value of 1, an unknown logic value (referred to as an ‘X’ value or “X-bit”), and a high-impedance logic value (referred to a ‘Z’ value or “Z-bit”) indicating an open circuit or un-driven portion of the IC design. In some cases, the known and unknown logic values may be referred to “logic signals” or “logic states” in the description below. The emulation processors may include any computational unit configured to perform logic computation for the purpose of emulating logic devices or logic systems. The emulation processor may include a Boolean-processor-based system, a field programmable gate array (FPGA), or the like.

In the context of emulation systems, emulating the signal and circuit behaviors of the user's IC design for unknown logic values X and a high-impedance values Z could be treated in the same manner and considered essentially indistinguishable for emulation purposes. The emulation processors model and emulate the X-bits and Z-bits in the same way when those bit-values drive inputs to circuit components (e.g., logic gates). As such, the emulator may only handle three (“ternary”) logic states (0, 1, X) to emulate the user's IC design, which operates with four (“quaternary”) logic states (0, 1, X, Z). Descriptions herein of an unknown value (X) also apply to the high-impedance value (Z). The descriptions herein of an unknown value X refer or apply to either X or Z values. The Z-bit indicates an un-driven signal Z occurring at a given portion of the IC design. As such, an un-driven signal Z effectively amounts to an unknown value X. As such, for the purposes of logical computation and compiling a netlist, the emulator treats an un-driven value Z the same as an unknown value X. In this way, the computational or functional operations of the emulator are basically executed using three potential values (e.g., 0, 1, X); the emulator need not distinguish between X and Z for the purposes of emulating the functions described herein, including emulating four-state logic circuits and emulating ternary memory. Rather than treating the four states (1, 0, X, and Z) with a quaternary logic function or three states (1, 0, and X (including Z)) as a ternary logic function, an emulation processor leverages the logic state of an unknown logic X to treat the unknown logic X as the unknown value it is intended to represent among the set of two binary logic states. As mentioned, this use of three states is possible because the unknown logic X is not an arbitrary logic value, but assumes one of the two binary states in the real circuit. The X-bits may be a useful representation in an emulation to account for certain indeterminate situations such as an unknown value before initialization due to, for example, powered-down components or resulting from timing violations. If the user's IC design includes four logic states, then software components of the emulation system (e.g., synthesis engine, compiler) may ingest, synthesize, or compile the user's IC design into netlist logic for modeling three-states of logic in the emulation hardware.

As mentioned, conventional emulators employ inefficient, or insufficient, techniques for modeling a “ternary memory” (three-state memory) of the user's IC design. The embodiments described herein include emulators having software and hardware for modeling ternary memories (sometimes referred to as a “user design ternary memory” or “virtual ternary memory”) of the user's IC design.

The software components of the emulation system perform various operations for obtaining the user's IC design and preparing logical representations of the user's design for emulation by the hardware. These operations generally include, for example, synthesis, compiling, partitioning, and scheduling. For ease of description, these functions are generally described herein as performed by a compiler, but any number of distinct software modules (e.g., synthesis engine, compiler, configuration manager, partitioner, scheduler) may perform these functions. In operation, the software of emulator obtains (e.g., receives or generates) one or more design files of the user's IC design, representing components (e.g., memories, logical devices) of the user's design in a hardware description language (HDL), such as Verilog or similar machine-readable format. The software's synthesis function may generate a netlist based on the design file, where the netlist contains logic representing structures and functions of components in the user's IC design. The netlist may be written in the same HDL (e.g., Verilog) or a different machine-readable format as the initial design files. The software compiles the logic of the netlist into machine-executable instructions (and, sometimes, user data content) for the hardware of the emulator to model the components of the user design. The emulator then parses and distributes he executable instructions (and data content) from the netlist to the emulator hardware for execution by the emulation processors. In some cases, the synthesis or compiling function of the emulator instantiates or generates additional instrumentation logic to support, augment, or replace portions of the netlist logic of the initially obtained netlist of the user. The instrumentation logic includes, for example, logic for overhead or administrative functions. As described herein, the emulator may take advantage of instrumentation logic as an improved technique for modeling user ternary memories or for modeling user memory corruption.

Modeling four-state values (0, 1, X, Z) and ternary memory grew increasingly critical with the increasing prevalence of four-state emulation systems. Certain circumstances recur in DUTs emulated by four-state emulators. These frequent circumstances are common sources of bugs in the IC designs, leading to verification challenges or oversights. Non-limiting examples of these circumstances include initial values of user memories; values driven by powered-down memories in designs for UPF devices; corruption of user memory from power-down operations in designs for UPF devices; incorrectly initialized or non-functional user memory interfaces; modeling out-of-bounds addresses in user memories; access to locations that have never been written; corruption of user memory from insufficient refreshing; and storage of unknown (X) values that originate from other sources in the user design (e.g., initial values of flops, signals driven by powered-down logic), among others. The benefits of X-modeling in emulator memories are not limited to modeling user memories as X-sources. The emulator memories are state elements for capturing inputs and outputs of user content and control bits of the user design that occur when emulating the DUT. Treating the emulator's memories as binary-only memory could conceal X-bits occurring in the user's circuit design. Concealing the X-bits could render moot the benefits of X-propagation (when emulating four-state logic).

The systems and methods described herein include emulators that implement “wrappers” comprising instrumentation logic for the emulator components (e.g., physical emulator memories or logic devices) to model user ternary memories in the user design and/or model certain memory-related functions, such as a Read, a Write, or an instantaneous corruption of user memory. These memory-related functions allow the physical binary memories of the emulator to behave as, or model, a user ternary memory in the user design. The memory wrappers include instrumentation logic adding support logic around portions of netlist logic for the user ternary memory, such as logic for memory port reads (MPRs) or memory port writes (MPWs) of the user memory. In some cases, embodiments generate the wrappers for the user memory, rather than performing conventional memory synthesis. The inputs include the user ternary RTL, as well as additional potential inputs for pre-compiler control. In operation, the emulator obtains the initial netlist logic representing the user ternary memories and distributes portions of the netlist logic to corresponding physical binary memories of the emulator. The emulator instantiates a distinct wrapper for each particular the user ternary memory in the user design. A user ternary memory is modeled by a combination of the initial netlist logic (performed or instrumented by a physical binary memory) and the instrumentation logic (performed or instrumented by a wrapper). The instrumentation logic of the wrapper provides functionality for the physical binary memory to model the user ternary memory, and model circumstances when there are unknown values (X) occurring at ports (e.g., inputs, outputs) of the user ternary memory.

The wrappers further support memory-related functions, such as generating warning or assertion signals to indicate the errors, and/or performing an instantaneous corruption of the user memory allocated to the designer's DUT. For instance, the wrapper checks whether user data content (e.g., data-in, data-out, stored data) or control bits (e.g., REN, WEN, A) of the user memories or user logic devices are all known (0 or 1), and permits the user memory to perform a particular operation (e.g., the memory value is written during a Write or the value is read/outputted during a Read). If the wrapper determines the user data or control bits contain X-bits, then the memories do not perform a memory operation since the user memory cannot know whether there should really be an access or not. Additionally or alternatively, the wrapper or emulator memory (or other component) issues a “warning” or assertion bit. In some embodiments, memory models may invalidate the entire user memory where control bits or address bits may or may not represent a write/read or where the write/read address is unknown. The wrappers configure the emulator memories to perform certain functions to invalidate or instantaneously corrupt the user memory.

For instance, due to the importance of power modeling (e.g., UPF modeling) in emulation systems, some embodiments implement the wrappers to emulate a memory corruption of an entire user memory of the DUT; for example, when a power domain of the user design that contains the user memory should model a power-down instance. Since conditions for modeling the memory corruption may occur in any cycle of the emulator, wrappers may corrupt the entire user memory all at once.

In some embodiments, the emulator employs physical flop devices (or “tag flops”) of the emulator hardware to model the instantaneous corruption of the user memory. When a tag flop is set or asserted, then a corresponding memory location of the user ternary memory is valid. The wrapper checks the status of the tag flop during a read, or updates the status of the tag flop during a write. The wrapper may prevent a read function (and thus inhibit further emulation) if the wrapper determines the tag flop is unset or un-asserted/de-asserted. To corrupt the user ternary memory, the wrapper unsets or de-asserts the tag flop during a write function. As an example, in operation, the wrapper instrumentation logic is configured to de-assert the tag flop device in response to the wrapper detecting an unknown logic state (X-bit) occurring in user content data or at a particular intended (or target) address during a Read function and/or during a Write function.

In some embodiments, the emulator employs a physical memory (or “tag memory”) of the emulator hardware to model the instantaneous corruption of the user ternary memory. A problem with the flop-based approach to memory corruption is that the number of user ternary memories of the user design could exceed a total number of available flop devices in the emulator hardware, or exceed a practical number of flop devices of the emulator hardware that would be practical or efficient to allocate to the user's design. The memory-based approach addresses this problem. The emulator allocates the tag memory and the user ternary memory to the user. The wrapper of a particular user ternary memory generates a key associated with the user ternary memory and updates a corresponding tag in the tag memory (e.g., the wrapper increments the current key and stores the updated key).

For instance, during a Write function, the wrapper generates a new current key and applies the current key on the user data being written. In some implementations, when applying the current key, the wrapper simply stores the current key into the tag memory location for the user ternary memory. In such implementations, during a Read (or later Write) function, the wrapper compares the current key against the tag. The wrapper determines the memory location is valid if the current key matches the tag that the memory location is invalid if the current key does not match the tag. The wrapper prevents a Read or Write function (and thus inhibit further emulation) if the wrapper determines that the location is invalid. To corrupt the user ternary memory, the wrapper increments the key to produce an updated key that does not match the current tag. During a later Read (or Write) function, the wrapper compares the key against the tag, determines that the updated key fails to match the current tag, and inhibits further memory operations. Additionally or alternatively, in some implementations, when applying the current key, the wrapper applies the current key on the user data according to a logic function (e.g., XOR), yield apparently randomized bits, and the wrapper stores the current key in the tag memory. During a later Read function, the wrapper fetches the current key from the tag memory corresponding to the user ternary memory location. To corrupt the user ternary memory, the wrapper increments the current key, rendering the stored user data in the ternary memory location unreadable. The memory corruption is approximated by changing the key between memory Read or Write functions, causing any user data Read that has not been written since before the last corruption event to appear randomized (e.g., a random mix of known bit values). When implementing the ternary memory, the wrapper performs certain desired behavior when a memory Read of user data that has not been written since the last corruption event looks like unknown logic states (X-bits), such that wrapper disrupts Reads or Writes of X-bits.

As an example, in operation, the wrapper is configured to update the value of the key corresponding to the tag associated with the user memory location in response to wrapper detecting an unknown logic state occurring at memory port, in user memory content, or at a target address location during a memory Read and/or during a Write function.

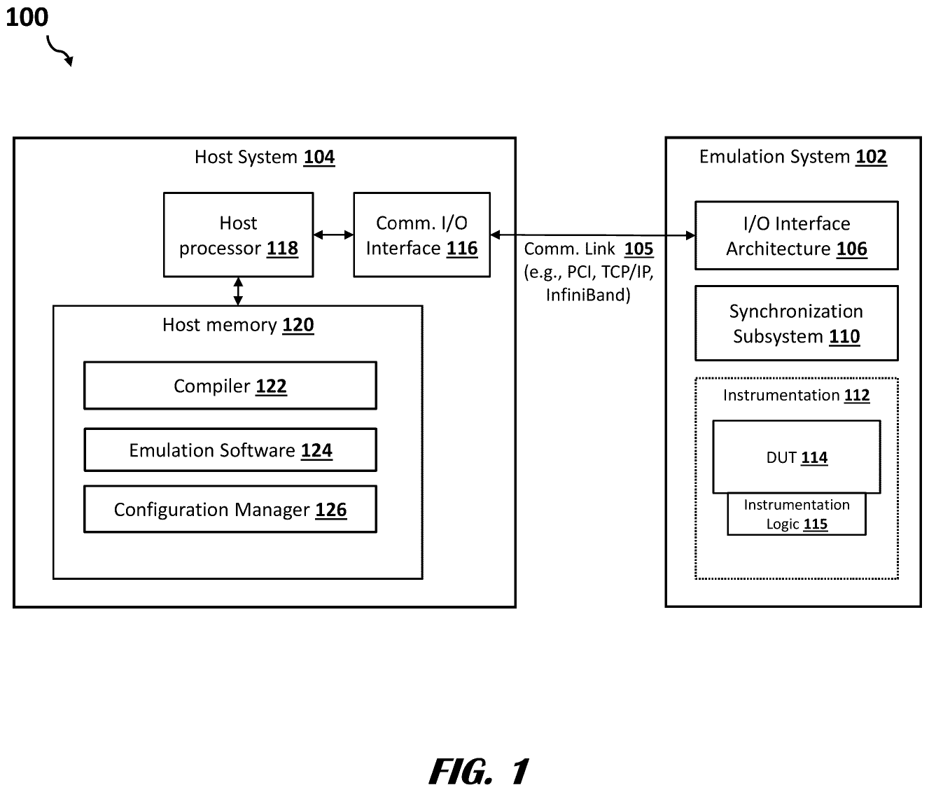

FIG. 1 shows components of a system 100 for emulation that supports representation of four-state signals or logic states. The illustrative system 100 may comprise a host system 104, and an emulation system 102. The host system 104 executes software (sometimes called a “test bench”) for managing operations of the emulation system 102, and communicates with the emulation system 102 via one or more communication links 105.

The host system 104 may include one or more workstations that may run debug and runtime software that may interact with the emulation system 102. The host system 104 may include workstations that may be any type of computing devices such as a desktop computers, laptop computers, tablet computers, and smartphones. The host system 104 may be any computing device comprising a host processor 118, a host memory 120, and one or more communication I/O interfaces 116. The host system 104 may further include any number of support circuits, such as cache memory, power supply, clock circuits, data registers, and the like. The host processor 118 of the host system 104 may include circuitry configured to execute the various processes and tasks described herein. Non-limiting examples of the host processor 118 of the host system 104 may include an x86 central processing unit (CPU), an ARM processor, a Reduced Instruction Set Computing (RISC) processor, an ASIC processor, or a Complex Instruction Set Computing (CISC) processor, among others.

The host memory 120 of the host system 104 may store various forms of software programs and files for execution by the host processor 118, such as an operating system (OS) and emulation software 124. The emulation software 124 includes as a compiler 122 and/or a configuration manager 126. The host memory 120 implementations may include, but are not limited to, a random access memory (RAM), a read only memory (ROM), a hard disk drive (HDD), a secure digital (SD) card, a magneto-resistive read/write memory, an optical read/write memory, a cache memory, or a magnetic read/write memory.

The communication I/O interface 116 couples the host memory 120 or the host processor 118 to the emulation system 102. The communication I/O interface 116 manages and/or interprets communications with the emulation system 102 over the communication link 105. The communication I/O interface 116 or other support circuit may also receive inputs from user interface devices (e.g., keyboard, mouse) for the OS of the host system 102, informing the OS to, for example, generate an interactive graphical user interface (GUI) to output on a monitor an interactive display configured to receive user inputs from the various user interface devices.

The compiler 122 comprises software configured to convert a hardware design netlist file (e.g., hardware described in a hardware description language (HDL)) into a sequence of processor-executable instructions that can be evaluated by a hardware emulator, executed by the emulation system 102. The compiler 122 may be executed on any number of devices, such as the host system 104 or emulation system 102 shown in FIG. 1, or another device. The compiler 122 may be a software module component of design or emulation software 124, which may be executed by the host system 104 or emulation system 102; or the compiler 122 may be a standalone software application configured to compile a design file, such as a netlist file.

In operation, the compiler 122 receives and compiles the netlist design file containing design elements into virtual logic of the compiled design, such as the logic gates, of the IC design currently being designed and tested (shown as DUT 114). The compiler 122 generates a virtual logic file (representing the IC's logic) based on the compiled netlist. The compiler 122 maps or otherwise associates the IC's logic and timing of operations into the hardware components of the emulation system 102, according to the design of the IC. The compiler 122 generates machine-readable instructions for the components of the emulation system 102 that cause the mapped components of the emulation system 102 to function as the DUT 114.

The compiler 122 may include a partitioner component and a scheduler component, though it should be appreciated that the compiler 122 may be segmented into any number of discrete component software modules. In an opening import phase, the compiler 122 receives a netlist and then begins compiling the netlist. Here, the compiler 122 parses the logic gates of the netlist into a database format. The partitioner determines which part of the netlist is going to be executed by which hardware resource of the emulation system 102. Then, the scheduler determines which of the hardware resources should execute the resulting instructions generated for each particular part of the netlist. The scheduler may also determine when in the execution lifecycle the virtual logic represented by the netlist should be executed.

The compiler 122 or other aspect of the test bench can generate and inject additional instrumentation logic 115, such as logic that manages or controls various aspects of the emulation system 102. In some cases, the compiler 122 (or other aspect of the test bench) generates additional instrumentation logic 115 that the compiler 122 may append to, or inject around, certain logic of the netlist. For instance, in addition to the compiled design logic of the netlist, the netlist further includes virtual logic that includes various logic or instructions related to device function, timing, synchronization, memory management, data transfers, and the like.

As an example, the compiler 122 generates memory “wrapper” instruction logic containing additional instrumentation logic 115 injected into the netlist (or virtual logic file), around the existing instrumentation logic 115 intended for a physical binary memory of the emulator 102. In this example, performing or instrumenting the logic of the wrapper in conjunction with the preexisting logic of a physical binary memory enables the physical binary memory of the emulator 102 to model a ternary memory.

The emulation software 124 tracks the status, and controls the performance, of components of the emulation system 102. The emulation software 124 may determine which components of the emulation system 102 are available or unavailable to receive parts of the virtual logic generated by the compiler 122. In some cases, the emulation software 124 continuously polls or self-tests the emulation system 102 for faulty hardware components. In some cases, the emulation software 124 may determine the status of components of the emulation system 102 when the virtual logic is being loaded into the hardware components of the emulation system 102. The designer can use the emulation software 124 to issue queries or instructions to the emulation system 102, such as requesting design-related information at certain points during the execution or instructing the emulation system 102 to execute from a certain breakpoint or for a certain number of steps/cycles.

A configuration manager 126 component of the emulation software 124 tracks the status of compiled instructions and controls the execution of instructions by components of the emulation system 102. The configuration manager 126 may determine which components of the emulation system 102 are available or unavailable to receive parts of the virtual logic generated by the compiler 122. In some cases, the configuration manager 126 continuously polls or self-tests the emulation system 102 for faulty hardware components, and may track the availability of various components of the emulation system 102.

The various software modules 122, 124, 126 may be executed in whole or in part on the host system 104, such as an administrator or IC designer's workstation computer, and configured to communicate data associated with the respective software module 122, 124, 126 to and from the emulation system 102. For example, in some cases, the host system 104 may execute the compiler 122 module that allows a user to input a netlist design file, containing logic gate designs of the prototype ASIC, and then compiles the netlist file. The resulting virtual logic file generated by the host system 104 may then be transmitted or otherwise downloaded to the emulation system 102. In this example, the emulation system 102 may execute the configuration manager 126 that tracks the availability of resources within the emulation system 102.

The emulation system 102 may be a combination of hardware and software components for emulating the DUT. As described below, the emulation system 102 may include clusters of emulation processors (e.g., clusters of interconnected ASICs), non-transitory memory devices, buffers, data storage devices configured for emulating the DUT. The emulation processor clusters may be arranged onto one or more circuit boards. The boards may be arranged within multiple racks. Multiple racks may be arranged in a plurality of emulation of devices, which may be analogous to multi-rack servers.

The emulation system 102 comprises an I/O interface architecture 106, a synchronization subsystem 110, and emulation instrumentation 112, which are logical aspects of the emulation system 102 comprising various hardware and software components of the emulation system 102. It should be appreciated that such logical aspects are mentioned for ease of description and understanding and are not necessarily boundaries or strictly defined sets of components. The I/O interface architecture 106 comprises hardware components for managing communications among components of the system 100. This subsystem provides a number of functions including, for example, providing the PCI interface 136 (or other types of interfaces for the communication link 105), communicating runtime communication (e.g., emulation job download, configuration, runtime control), and exchanging various types of design data, among other potential functions. The interface architecture 106 comprises an Internal System Bus (ISB) which allows transfer of data internally between target devices, such as block register interfaces and internal and external memories, back and forth with the I/O Buffers (IOBs) and ultimately PCIe.

The synchronization subsystem 110 is a logical collection of hardware and/or software components responsible for maintaining synchronization and controlling execution timing of components of the emulation system 104. At runtime, the emulation system 102 uses the communication link 105 to download design data, configures the synchronization logic, and initializes or uploads any design memories to the test bench as instructed. Configuration and control of the synchronization system 110 is done over the communication link 105 (e.g., Infiniband) to a data processing unit (DPU) and/or to the respective FPGAs.

The emulation instrumentation 112 comprises hardware components (and sometimes software) for executing the virtual logic of the DUT 114, transferring design and/or control data between components, and managing the execution. The emulation instrumentation 112 may include an emulation engine configured to be a programmable device used in the verification of hardware design of DUT 114. The emulation instrumentation 112 may test and verify the operation of the DUT 114, an entire board of ICs, or an entire system, without having to actually, physically fabricate the hardware. The emulation instrumentation 112 generally comprises any number of racks with any number of emulation boards, organized logically into any number of board clusters. Each emulation board comprises one or more emulation chips 130, such as an ASIC. The emulation chip 130 comprises several reprogrammable emulation processors, often organized logically into any number of processor clusters 132. The emulation processors mimic the logic gates (or other logic/devices) of the DUT 114. The emulation system 102 may include any number of programmable logic devices (PLDs), such as field-programmable gate arrays (FPGAs), to perform or manage aspects of the emulation. Such devices may be coupled to an expansion board or other printed circuit board for communication via a bus or link, such as a PCI (or PCIe) bus or serial bus.

The communication link 105 comprises any number of computing hardware and software components establishing a bus or link between computing devices using any number of communication protocols. In operation, the communication link 105 conducts data and/or instruction transfer between the host system 104 and the emulation system 102. Non-limiting examples of the communication link 105 include Peripheral Component Interconnect (PCI), which may include PCI express (PCIe), TCP/IP, and InfiniBand, among other types of communication links 105.

For emulating user-design ternary memories, the compiler 122 compiles the netlist such that the properties or functions of user-design ternary memories, such as memory ports and port functions (e.g., MPRs, MPWs), appear the same as in the case of a physical binary memory. For an instance of a user-design ternary memory, the compiler 122 instantiates the instrumentation logic 115 of the wrapper around the netlist logic for user memory components intended for physical binary memory, but the wrapper logic augments or replaces portions of the netlist logic (e.g., logic for MPRs and MPWs). Together, the combination of the initial netlist logic and the wrapper logic allows the physical binary memory to model the user-design ternary memory. The wrapper logic performs certain ternary-memory functions, such as performing transformations or translations of ternary (or quaternary) signals on behalf of the physical binary memory during a Read or Write function, or performing certain specified functions when the wrapper logic detects an unknown logic state (X) at a particular port of the physical binary memory.

In some implementations, the user ternary memory, a user-design memory or memory function outputs (according to the wrapper logic) a virtual output signal, such as a SYNC virtual output signal of the user memory, which is marked as a binary signal or ternary signal to indicate the property of whether the user-design memory content data is binary or ternary. In such implementations, multiple ports of multiple user memories and/or memory hardware components may be “chained” together to facilitate certain ternary memory functions. The SYNC_IN and SYNC_OUT ports, which receive and output the SYNC virtual output, indicate that the inputs or outputs of the user memory components are associated across the chain of user memory and/or hardware memory components.

In some implementations, when compiling and instantiating the netlist logic of the initial netlist and the instrumentation logic 115 of the wrappers for modeling the user-design ternary memories, the scheduler treats the control bits of the memory as binary and the data content bits as ternary. The user-design memory compiler 122, as changed, adapted, or configured for ternary memories, may maintain a count of the ternary memories, which require twice the physical data width compared to binary memories. In some cases, the software of the compiler 122 executes one or more additional heuristic optimizations for identifying or selecting the available physical memories of the emulation hardware.

The compiler 122 instantiates the instrumentation logic 115 of the wrappers for modeling ternary memories and ternary memory functions using the physical binary memories. Beneficially, implementing the user-design memory control bits as binary bits (often required by physical binary-based memory hardware of the emulation system 102) does not preclude handling ternary signals and ternary memories (which the wrapper logic enables the emulation system 102 to emulate using the physical binary-based memory hardware of the emulation system 102). Rather, in some implementations, wrapper logic enables the emulation system 102 to handle the memory control bits in such a way that the treatment of these memory control bits is independent of the netlist presented to the scheduler or the compiler 122. Due to the potential of bits representing an unknown logic state (X-bits) in the memory control bits, the handling of the necessary behaviors may be represented as the instrumentation logic 115 of the wrappers. The combination of the initial netlist logic of a physical binary memory and the wrapper logic of the corresponding wrapper, together, represents or models the particular user-design ternary memory, memory components (e.g., ports), and various memory-related memory functions (e.g., MPR functions, MPW functions). As an example, for a given user-design ternary memory identified in the DUT 114 by the compiler 122, the combination of the (initial or modified) netlist logic of the particular physical binary memory (scheduled to model the user-design ternary memory) and the wrapper logic of the wrapper (instantiated for the particular user-design ternary memory and merged around the netlist logic of the physical memory) together model the user-design memory functions (e.g., Read, Write) The compiler 122 instantiates the wrapper as additional instrumentation logic 115 that the compiler 122 merges with the initial netlist logic representing the user-design ternary memory functions, around the portion of the netlist logic scheduled for the physical binary memory intended to model the user ternary memory.

The compiler 122 instantiates the wrapper according to various parameters as indicated by properties of the user-design memory or user selected options for modeling a user-design ternary memory. For instance, the compiler 122 automatically determines, or the user manually inputs, certain parameters that define a certain memory width (e.g., W-bits wide) and memory depth (e.g., D-locations deep) of the physical memory hardware assigned to the user memory, which the compiler 122 (or other software program) selects from the memory hardware of the emulation system 102 and, in some cases, as indicated by the instrumentation logic 115 of the wrapper.

In some implementations, the compiler 122 instantiates instrumentation logic 115 for one or more tag bits associated with portions of the user memory that function as a tag indicating whether the whether the data at a particular user-memory location should be treated as an unknown logic state (X). The emulation system 102 may logically and/or physically model or represent the user memories as arrays. The compiler 122 assigns the user memories as the arrays to the physical memory of the emulator hardware and assigns the tag bits to portions of the array, according to the netlist and/or the wrapper logic instantiated by the compiler 122. In such implementations, the tag bit assigned to each row of the array indicates whether the content data at that particular row or address should be treated as unknown logic state (X). In this way, the tag bit indicates whether the content at the particular location is currently unknown.

In some circumstances, when modeling four-state logic, the logical memory arrays of the user-memory could contain any number of X-bits representing unknown logic states (e.g., unknown values stored as the user-memory content data). The compiler 122 generates the netlist or the wrapper to indicate various memory-related functions that the memory hardware performs in an emulation. The compiler 122, for example, instantiates wrappers to perform certain memory functions when one or more X-bits arrive or occur at ports or control pins of the user-design memory or at underlying physical binary memory hardware modeling the user ternary memory.

In some implementations, the wrapper includes memory corruption instructions that corrupt the user-design ternary memory of the user memory. Ordinarily, the physical memory hardware applies a key on the user content data (e.g., performs an XOR function using the user data and the key) when performing memory-related functions, such as a typical Read or Write function. When X-bits arrive or occur at the physical binary memory hardware, the netlist logic causes the physical binary memory hardware to perform a Read or Write instruction using a different key, creating the appearance of random or corrupted user content data. The memory corruption functionality may be shifted to the instrumentation logic 115 of wrappers. When a user ternary memory performs a write function, the wrapper generates and applies a key to the user data, and then the wrapper (or some other memory location of the emulation system 102) stores the key. In some cases, the wrapper applies the key to the user data using the XOR (or other) function. Additionally or alternatively, in some cases, the wrapper stores the key separately as a tag in the wrapper or in a separate physical storage component of the emulation system 102 (e.g., tag flop, tag memory). During a Read function, the wrapper of the user ternary memory (or the wrapper of another user-design component) applies the key to the user data or compares the key against the tag. To corrupt the user memory, the wrapper changes or updates the key at some point before the Read function.

Alternatively, the wrapper logic recognizes a user ternary memory location as valid and readable when a corresponding flip-flop (e.g., tag flop) is asserted (“set”) or invalid when the tag flop is un-asserted or de-asserted (“unset”). The wrapper checks the status of one or more tag flops before performing a particular function, and performs certain operations accordingly. The wrapper also checks and/or updates the status of a tag flop according to the wrapper logic. For example, the wrapper may prohibit a memory Read if the wrapper determines the tag flop is unset, or the wrapper may unset the tag flop to instantaneously corrupt the corresponding user memory.

In some implementations, when the wrapper identifies unknown bit values occurring on the control pins, the wrapper outputs (or causes the memory hardware or other hardware of the emulation system 102 to output) a “warning” bit or signal and/or halt further action or further emulation cycles. The software of the emulation system 102, such as a trace subsystem, translates the warning into human-readable trace information or debug information presented at the user interface 108.

Below, TABLE 1 shows non-limiting examples of memory-modeling options that may be implemented by the instrumentation logic of wrappers. In operation, the wrappers include instrumentation logic that, together with the logic of the netlist, enable the physical binary memory of the emulator hardware to model the user ternary memory and certain optional functions, including logic for functioning as a ternary memory in logical arrays of the user memory, logic for performing memory corruption functions, logic indicating tags associated with portions (e.g., bits, bytes, array rows) of the user memory, and logic for handling unknown logic states (X-bits) in the content data or control bits received or outputted at ports of the user memory, among other possible functions related to the user memory.

TABLE 1

| | Hardware | Extra HW | Supports | |
|---|---|---|---|---|
| Labeled | (HW) Mem | Flops or | Instant | |
| Functionality | Size | Tag | Corrupt? | Description |
| Binary | Width (W) × | Key: | Yes | Current Solution. User memory |
| | Depth (D) | W flops | | does not model ternary content, but |
| | | | | fakes corruption by randomization. |
| | | | | “Read” function corrupts memory |
| | | | | and returns a random mix of 0s and |
| | | | | 1s. |
| | | | | din = DIN \hat{ } key |
| | | | | DOUT = dout \hat{ } key |
| Bin + 1 | (W + 1) × D | 0 | No | Tag each row with one bit in |
| | | | | memory. Models ternary content |
| | | | | only if entire word is X. |
| | | | | DOUT = tag[a] ? ′bx: dout |
| Bin + 1F | W × D | Tags: | Yes | Tag each row with one bit in |
| | | D flops | | flops. The user memory models |
| | | | | ternary content only if entire word |
| | | | | is X. |
| | | | | DOUT = tag[a] ? ′bx: dout |
| Tern | 2W × D | 0 | No | Ternary Base Model. User |
| | | | | memory models ternary user |
| | | | | content data. |
| TernR | 2W × D | Key: | Yes | Ternary + Randomization. Keeps |
| | | 2W flops | | randomization key; the “Read” |
| | | | | corrupts memory and returns |
| | | | | random mix of {0, 1, X} |
| | | | | din = DIN \hat{ } key |
| | | | | DOUT = dout \hat{ } key |
| Tern + 1 | (2W + 1) × D | 0 | No | Ternary + Tag. User memory |
| | | | | models ternary content data and |
| | | | | tags each row of the array with one |
| | | | | bit in memory. |
| | | | | This function could be redundant |
| | | | | with TERN (above). |
| Tern + 1F | 2W × D | Tags: | Yes | Ternary + Tag. User memory |
| | | D flops | | models ternary content data and |
| | | | | tags each row of the logical array |
| | | | | in flops. |
| | | | | Corruption: tag[ ] = ′b0 |
| | | | | When writing, set tag[a] = 1 |
| | | | | DOUT = (tag[a] == 0) ? ′bx: dout |
| Tern + T | (2W + T) × D | 0 | Yes | Ternary + Multibit Tag. User |
| | | | | memory models ternary content |
| | | | | data and selects T bits as a tag or |
| | | | | key. Each instance of corrupting |
| | | | | the memory, the emulator selects a |
| | | | | new key. The key can simply |
| | | | | increment through all available |
| | | | | values. |
| | | | | Corruption: key++ |
| | | | | When writing, set tag[a] = key |
| | | | | DOUT = (tag[a]! = key) ? ′bx: dout |
| | | | | After a number (2^{T}) of corruption |
| | | | | events, some locations in the user |
| | | | | memory may contain an old tag |
| | | | | that matches the current key |
| | | | | resulting in a “key overflow.” But |
| | | | | after the key overflow, the |
| | | | | emulator generates a warning or |
| | | | | assertion |
| Tern + TR | (2W + T) × D | Key: | Yes, | Ternary + Multibit Tag + |
| | | 2W flops | almost | Randomization. User memory |
| | | | | models ternary content data, with a |
| | | | | workaround for key overflow by |
| | | | | performing bit randomization. The |
| | | | | memory normally returns ‘X’ for |
| | | | | the corrupted locations. But after |
| | | | | the key overflow, the memory |
| | | | | returns random mix of {0, 1, X} |
| Tern + Scrub | (2W + T) × D | 0 | Yes | Ternary + Multibit Tag + Scrub. |
| | set T~ | | | User memory models ternary |
| | log₂D~NA | | | content data, with a workaround |
| | | | | for key overflow by scrubbing tags. |
| | | | | The emulator creates additional |
| | | | | read and write port for a scrub |
| | | | | function. The emulator iterates |
| | | | | through the user memory across |
| | | | | successive cycles. At each cycle, |
| | | | | the memory reads one location |
| | | | | from the memory and rewrites the |
| | | | | data with a newest invalid key. |
| | | | | This ensures that the tag at a |
| | | | | location in the memory is never |
| | | | | older than the number of cycles |
| | | | | needed to scrub the tags. |
| | | | | If the emulator sets the size of the |
| | | | | tag to log₂D, then the keys are |
| | | | | always good. |
| | | | | If the emulation is IXCOM, then |
| | | | | emulator cycle or time may be |
| | | | | stopped when the key overflow is |
| | | | | imminent, and the tag could be |
| | | | | much smaller. |

In some embodiments, the wrapper's memory corruption or tagging operations perform byte-enabled functionality at a byte-level. The byte-enable support could interfere with the various tagging methods. However, there is an advantageous restriction in the memory corruption. Memory corruption corrupts the entire memory, so the memory corruption is orthogonal to byte-enable support. As such, there is no need to be able to corrupt bytes individually. In this way, generally the tagging approaches could be shared across the entire memory location. As an example, the possible modeling options that do not tag entire memory locations with a single tag could use hardware byte-enables. As another example, the possible modeling options that can represent X-bits (or approximate X-bits through randomization) could support byte-enables by always performing “read-modify-write” (RMW) operations in the circumstances of a write and supplying the X-representation in the unwritten bytes if a memory line was invalid or for the bytes that already contain X-bits. As another example, the modeling options that cannot represent the X-bits for individual bytes also cannot support byte-enables except by treating each byte as a different user-design memory or physical memory.

In some implementations, according to the wrapper, the unknown values (X-bits) on control signals (including an address) raise an assertion or generate a warning signal (which may, for example, be displayed at the user interface 108). For given conditions involving X-bits occurring at a memory pin (sometimes referred to as a port of user the memory), the memory wrapper instructs the memory hardware (or other hardware) to generate a one-bit signal (e.g., assertion, warning) indicating the given condition. The error assertion or warning message indicates certain information associated with the memory hardware having the X-bits, such as the time of the X-bits, memory port of the memory having the X-bits, and the values of control bits (e.g., CE, WE, RE) or memory content (e.g., ADDR, data at ADDR). In some cases, the wrapper or user memory generates a warning when a key overflow is detected, when the memory hardware does not perform a write because a number (2\hat{ }T) of corruption events occurred. This may occur, for example, when the memory wrapper implements the TERN+T memory-modeling option.

The emulation system 102 may generate one or more messages for the user interface 108 when the emulation system 102 attempts access a memory containing X-bits on the control bits and/or the content bits. Each memory wrapper generates a variety of outputs related to the certain conditions or corruption events, and software and hardware components of the system 100 provide some sort of message to the user interface 108. In each warning or assertion, the designer and emulation system 102 references the given waveforms at the time of the warning or assertion to identify or determine the portion of the memory and cycle time associated with the warning or assertion. Non-limiting examples of the warnings or assertions include a true assertion, a DPI message, and an instrumentation sticky bit, among others. The true assertion indicates that a given event occurred for conditions consistent with the designer's expectations or the designer's test. The DPI message assertion generates a message to the designer using DPI-based messaging functions (e.g., $display). The DPI message assertion fires for a condition, for example, consistent with a given logical test or consistent with other messages generated by the DUT 114, and according to memory model options that control printing messages. The sticky bit assertion creates one or more sticky bits that, at runtime, cause the emulation system 102 to query the signals and add messages to the log files for tracing by the designer. In some cases, the designer may deposit or force the sticky bit(s) as desired to function as a mask or to reset corruption events. The emulation system 102 transmits the messages or log files to the host system 104 and/or displays the messages or log files at the user interface 108, allowing the designer the opportunity for debugging.

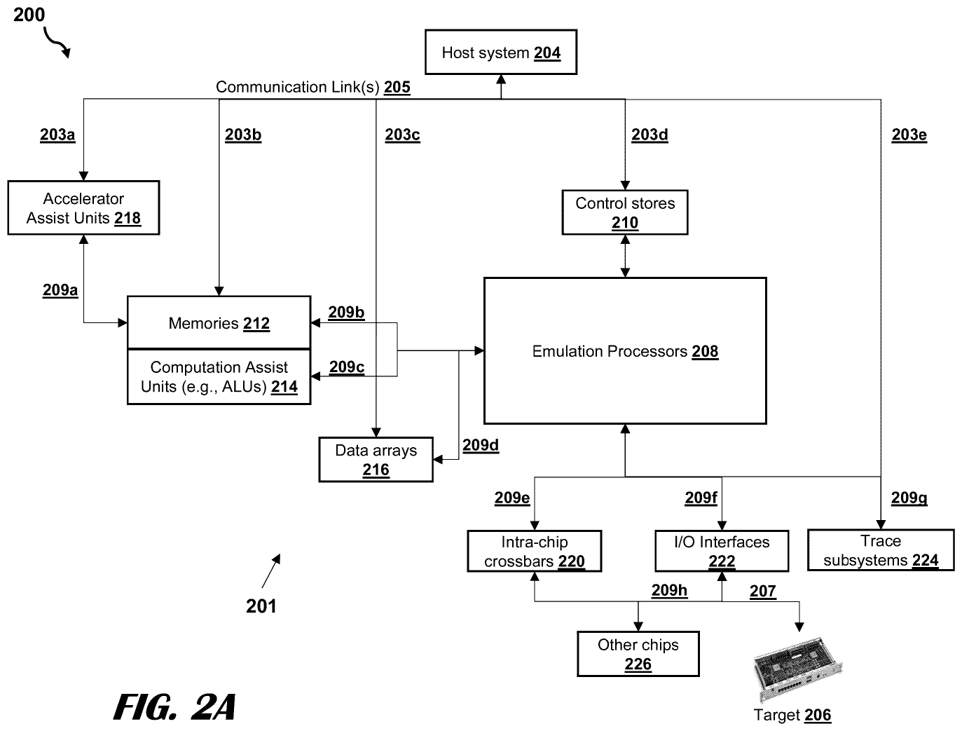

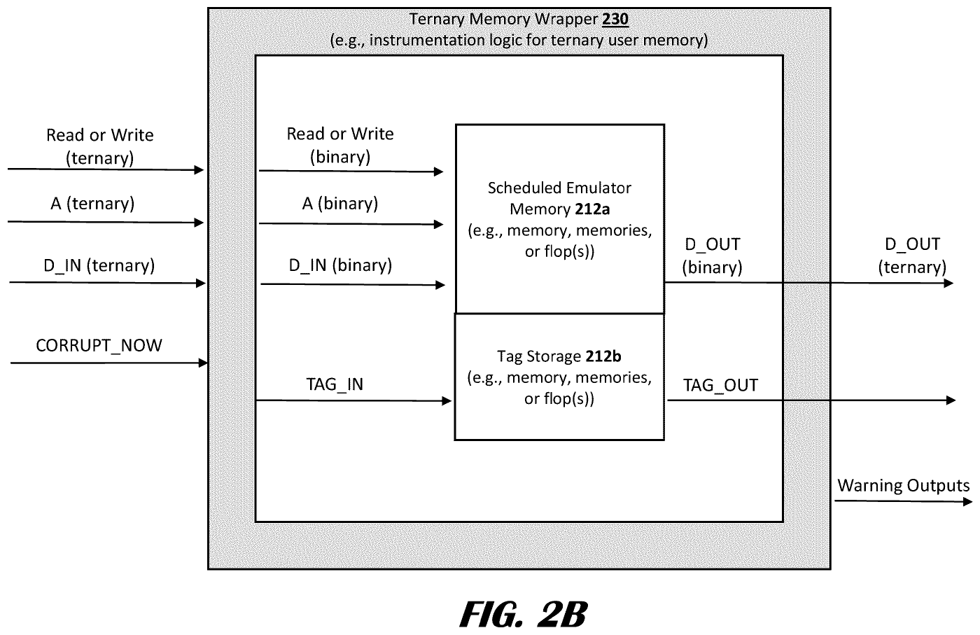

FIG. 2A shows components of a system 200 for performing emulation processes described herein, which includes depicting components within an emulation chip (e.g., ASIC 201) of an emulation system (e.g., emulation system 102 of FIG. 1). FIG. 2B depicts a logical (rather than a literal or entirely physical) representation of a user-design ternary memory wrapper 230 being instrumentation logic “wrapped” around certain physical hardware components of the emulation system. The system 200 includes a host system 204 (e.g., host system 104 in FIG. 1), the emulation system, and a target system 206. The emulation system includes any number of emulation chips or similar hardware (e.g., ASIC 201, other chips 226).

The example ASIC 201 comprises emulation processors 208, control stores 210, memories 212, computation assist units 214, memory data arrays 216, simulation acceleration assist units 218, intra-chip crossbars 220, input/output crossbars and interfaces (I/O interfaces 222), and trace subsystems 224. One or more interconnects 209a-209h (collectively or commonly referred to as interconnects 209), such as wires, connect the components of the ASIC 201. One or more communication links 205 (e.g., communication links 105 in FIG. 1) connect the host system 204 with the ASIC 201 as connections 203a-203e of the communication links 205 (collectively or commonly referred to as connections 203). One or more connections 207 (e.g., connection 107 in FIG. 1) connect the target system 206 with the hardware of the emulation system (e.g., ASIC 201, other chips 226).

The ASIC 201 includes a large number of emulation processors 208 (e.g., Boolean processors) that perform the functions of the IC design during emulation. An emulation processor 208 of the emulation processors 208 may be any computational unit configured to perform logic computation for emulating (or modeling) logic systems of a DUT. For instance, the emulation processors 208 may include reprogrammable logical hardware, such as Boolean processor-based systems, FPGAs, or the like. The control store 210 includes any number of machine-readable non-transitory storage accessible to, or otherwise associated with, the emulation processors 208. The control store 208 includes, for example, instruction memories containing instruction sets (generated from netlist logic) for execution by components (e.g., the emulation processors, multiplexers, memories 212) of the emulator. In operation, the emulator loads the machine-executable instructions (representing the logic of the netlist) into the storage locations of the control store 208 associated with the emulation processors 208 (or other components of the emulator), and the emulation processors 208 retrieve (or other components of the emulator)the machine-executable instructions from the control store 210 (or other storage location) for executing (or instrumenting) the instrumentation logic in order to model the logic components of the given DUT. The emulation processors 208 then execute the logic over one or more emulation cycles of the emulation system. The logic could be the same for different emulation cycles, and the data on which the logic operates may change because of the change in the states of the DUT from one cycle to another. The state data represent, for example, the state of the DUT's state elements, intermediate combinational nodes (e.g., multiple devices functioning as a more complicated device), and states of design memories.

The memories 212 of the emulation system comprise various types of physical binary memories, performing various functions or operations. For ease of description, the memories 212 in FIGS. 2A-2B include portions of the scheduled emulator memories 212a allocated to the designer's DUT and, according to the netlist logic of the netlist and instrumentation wrapper logic of the wrappers 230, model the user-design ternary memory (sometimes referred to as “user memory” or “user ternary memory”). The memories 212 include hardware components for storing bits of user content data or control bits, where the memories 212 include memory-based memory 212 comprising a type of machine-readable memory (e.g., RAM, INTRAM) or flop-based memory 212 comprising flip-flops, latches, registers, or the like. The memories 212 store, for example, the state data, state elements, and other information related to or generated by the designer's emulated DUT, user data, control bits, and/or user memory content data. In some embodiments, additional or alternative storage components (e.g., data arrays 216) of the system 200 define the user memory, allocated by the emulation system to the designer DUT for implementation as the ternary memory. The emulation system logically and/or physically organizes the memories 212 of the emulation system as arrays when the allocated to the DUT as the ternary memory. In some embodiments, the wrapper 230 generates and stores tag bits in the wrapper logic for certain memory-related functions, or stores the tag bits in the scheduled emulator memory 212b. In some embodiments, the emulation system allocates the scheduled memory 212a and tag storage 212b for storing the tag data, where the tag storage 212b may include flip-flops and/or machine-readable memory (e.g., INTRAM, RAM). The ternary memory wrapper 230 transforms or translates ternary signal data to/from binary signal data based upon parameters mapped to the wrapped scheduled emulator memory 212a, such as size, addresses, or port definitions (types of ports, types of port functions), among others.

For instance, embodiments in which the emulation system comprises flop-based memories 212, the emulation system compiles the netlist logic and instantiates the wrapper logic 230 in order for the physical binary memories 212 to model ternary memories that may contain an unknown value (X). In some implementation, the memory wrapper 230 uses flop-based memories 212 for converting the DUT's control signals from ternary to binary at a port of the user ternary memory. In this way, the control signals applied to the flop-based memory 212 are never unknown X-bits. The logic of the wrappers effectively convert the control signals and/or data content of the DUT from ternary (or quaternary) to binary signals or vice-versa. The logic of physical binary memory 212, together with the logic of the wrapper 230, enable the logic states of the flop-based memory 212 to handle binary signals when modeling logic states in the arrays of the memories 212 as ternary logic states. The storage flops themselves, and related “Read” multiplexing logic, may effectively be duplicated to handle the two-bit representations of the ternary memory content. However, the one-bit control logic need not be ternary-capable because the control bits (WEN, REN, A) are always binary and never ternary after the transformation by the wrapper logic 230.

A cluster of emulation processors 208 (typically a cluster of eight emulation processors 208) executes the logic (e.g., netlist logic comprising original logic and wrapper logic) of the DUT and stores the state information into one or more data arrays 216, assigned to the emulation processors 208. In some embodiments, the cluster of emulation processors 208 may store the states into other larger memories 212, which may include an internal RAM memory (INTRAM) and/or external RAM memory (EXTRAM).

In some embodiments, the ASIC 201 may further include one or more computation assist units 214 that the ASIC 201 uses to model certain functions, including functions not efficiently handled by general-purpose bitwise processors or generic memories. The computation assist units 214 include hardware structures that, for example, perform arithmetic operations, such as arithmetic logic units (ALUs). Additionally or alternatively, the ASIC 201 includes acceleration assistance units 218, which may include embedded microprocessors, performing local processing of simulation acceleration or analysis tasks in the ASIC 201. In some cases, the acceleration unit 218 implements the local processing in the ASIC 201 along with acceleration operations executed at the host workstation 204.

The intra-chip crossbars 220 provide an interface for the emulation processors 208 to interact with the other processors of other ASICs (e.g., other chips 226). The I/O interfaces 222 may provide an interface for the ASIC 201 to interact with the target systems 206 or external other chips 226. The target systems 206 and the other chips 226 may provide an external hardware environment for the DUT being emulated by the emulation system.

The trace subsystem 224 collects and/or stores bits or signals generated in the ASIC 201 (or other aspect of the emulation system), outputted during execution of the DUT. The trace subsystem 224 may function in concert with other software components of the emulation system, such as a compiler and debugging tool for runtime or offline code debugging, where the trace subsystem 224 collects, stores, and interprets, for example, the outputted bits or signals (generated by the ASIC 208) or the memory states (in the memories 212 or data arrays 216). The trace subsystems 224 support, for example, one or more general modes of operations, such as dynamic probes (allowing a set of user-specified probes of hardware components with deep traces), or full vision (allowing reconstruction of all user signals without user specification and without performance impact), among others.

The compiler may generate various types of wrappers 230 including wrapper logic that (together with the netlist logic for the physical binary memories 212) enables hardware components of the emulation system to model ternary memories and/or model particular functionality (e.g., instantaneous corruption). In some cases, the types of wrappers 230 may include a bit-randomization wrapper (+R) uses bit-randomization to model instantaneous corruption (which fakes corruption by randomizing the bits). In some cases, the types of wrappers 230 may include a tag-bit wrapper (+T) or a one-bit tag-in-a-flop wrapper (+1F), which perform instantaneous corruption by either contemporaneously unsetting all the one-bit tags (+1F) or changing a key (+T) in the tag storage 212b. In such cases, the corruption happens instantaneously, and the wrapper logic changes the tag (or compares the tag against the key) to determine whether the read data should be presented to the user logic as an ‘X’ or as the stored memory content.

In some implementations, the logic of the wrapper 230, in conjunction with the physical binary memory (or flops) of the scheduled memory 212a, enables the emulator to model binary data content data (not ternary user content data), and to model particular functions (e.g., instantaneous corruption). As an example, the logic of a wrapper 230 (BIN+R) includes logic that (together with the initial netlist logic intended for the physical binary memories) enables the emulator to model bit-randomization, which fakes memory corruption. The Read function corrupts the memory 212a and returns a random mix of binary values (random mix of 1s and 0s).

As another example, the logic of a wrapper 230 (BIN+1) includes a tag for each row of an array with one-bit in memory, enabling the logic of the physical binary memory 212a and of the wrapper 230 to model ternary content only if bits for an entire word represent an unknown X. As another example, a wrapper 230 (BIN+1F) includes a tag for each row of an array with one-bit in memory, enabling the logic of the one or more flops of the scheduled memory 212a or tag storage 212b and of the wrapper 230 to model ternary content if bits for an entire word represent an unknown logic state X.

In some implementations, the logic of a wrapper 230 (TERN), in conjunction with the physical binary memory (or flops) of the scheduled memory 212a, enables the emulator's physical binary memory to model ternary user content data. As another example, a wrapper 230 (TERN+1) models ternary content data, and tags each row of the array with one-bit in user-design memory, the wrapper 230, the scheduled memory 212a, or tag storage 212b.

In some cases, the wrapper 230 enables the emulator to model ternary memory content and particular functions (e.g., instantaneous corruption). As an example, the logic of a wrapper 230 (TERN+R) configures the physical binary memory 212 of the emulator to model ternary memory and to model instantaneous corruption using bit-randomization. The wrapper logic generates and/or maintains a key, which is referenced (e.g., checked, applied) during Read operations to corrupt the memory and, in some embodiments, return random mix of ternary values {0, 1, X}.

As another example, a wrapper 230 (TERN+1F), models ternary content data in scheduled binary memory 212a, and tags each row of the logical array in one or more flops of a tag storage 212b (or other storage location). In this example, the wrapper 230 models instantaneous corruption by resetting each of the one-bit tags in the flops of the tag storage 212b.

As another example, a wrapper 230 (TERN+T) models ternary content data in scheduled binary memory 212a, and selects a number (T) of bits as a tag or key for a tag storage 212b. Each instance of corrupting the memory, the wrapper logic of the wrapper 230 (or other software of the emulator or logic of the DUT) selects a new key by incrementing through a set of available values. The wrapper logic changes the tag (e.g., during a Write) or compares the tag against the key (e.g., during a Read) to determine whether the written/read data should be presented to the user logic as an ‘X’ or as the stored memory content. Further discussion of these examples is found below. The examples described here and shown in TABLE 1 are not limiting on the types of wrappers 230 or modeling-options that could be implemented using wrappers 230.

The TERN wrapper 230 provides X-support handling on the memory control signals. On an input side or output side of the logic of a particular (wrapped) memory 212a, the logic of the wrapper 230 injected around the memory logic includes logic to, for example: detect X-bits at an address, at byte select or at a function-enable (for read or write port); prevent memory writes when any X-bits occur on an address or enable function; controls a multiplexer (MUX) on a data output to be an X-bit; and flags or indicates error conditions. As an example, the data output by the wrapper logic of the TERN wrapper 230 is an unknown value X if an enable function for the given port includes an X-bit or any address bit includes an X-bit. An X-bit occurring at the enable or any byte selects for a write port causes an error condition about an unknown-value write.

The TERN+IF wrapper 230 adds logic support for instantaneous corruption by adding a corruption input signal (CORRUPT_NOW), which may be driven by another component of the emulation system (e.g., precompiler). The corruption is further supported by logic specifying a number of flops or depth of the scheduled memory 212a (or tag storage 212b) to be used as tags (TAGS), where one flop is used for one address and is set to ‘1’ to indicate the address holds valid data. To instantly corrupt the entire user ternary memory on the rising edge of the CORRUPT_NOW signal, each of the tag flops are written back to ‘0’ within one clock (folk). To corrupt any one particular address in the user ternary memory, the corresponding tag flop is set to ‘0.’ Optionally, a parameter X_CORRUPTS_ALL allows for any single illegal write to corrupt the entire user memory, as opposed to an illegal access only affecting the read to the address. After the user memory is corrupted, any partial write (e.g., a write with byte selects enabled) needs to write X-bits for any bytes not selected.

The TERN+1F wrapper 230 includes logic that checks the tag flop in the tag storage 212b to determine whether the address is valid, and if not, modifies the user content data (data_in) to unknown X-bits and then writes all bytes into the user memory (and physical scheduled memory 212a). If the address is valid, then only selected bytes are written. For memory dumps, the wrapper logic of the TERN+1F wrapper 230 reads, or instructs the runtime instrumentation logic of the memory 212a or wrapper logic 230, to read a given tag-flop. If the tag-flop contains a 0, then the logic of the wrapper or of the memory outputs an unknown value (X-bit). For memory loads, the logic of the wrapper or of the memory sets a given tag-flop to 1.

The TERN+T wrapper 230 supports instantaneous corruption in ternary memory by using a separate memory-based (rather than flop-based) tag memory as the tag storage 212b, which is T-bits wide. The TERN+T wrapper 230 instructs the scheduled memory 212a to perform a user-data write to an address and the wrapper (or other component) writes a current key (KEY) to the tag memory 212b. The wrapper 230 blocks the write if there is an X-bit on the enable, address, or byte select inputs. When the wrapped memory 212a performs a Read from an address, the Read function returns an X-bit if the wrapper logic 230 determines the tag for the corresponding address does not match the key or if the wrapper logic 230 determines there is an X-bit on the enable or address inputs.

The TERN+T wrapper 230 includes logic that may instantly corrupt the entire user memory on the rising edge of a CORRUPT_NOW input signal. The wrapper 230 updates (e.g., increments) the value of the current key (KEY), such that each address no longer corresponds to a valid tag. In the wrapper 230 implementing the TERN+1F memory-modeling option, only one bit is needed because each of the bits used for tags could be written in one cycle, whereas the wrapper 230 implementing the TERN+T memory-modeling option uses a key (T-bits wide) to store the valid tag and modifies the current key to cause the instantaneous corruption. The number (T) of tag bits can be increased to lessen the chances of a key overflow, where the key overflow occurs, for example, when invalid data should show as X-bits, yet appear as valid data.

In some implementations, to minimize the time needed to arrive at a key overflow, the wrapper 230 does not change the key if there is not Write on the user memory between corruption events, unless a user command is issued to manually modify the user memory. To notify the wrapper logic of a user memory write, the emulation runtime logic deposits a ‘1’ into storage location accessible to the wrapper 230 and indicates whether there has been a Write since the last corruption, such as a WRITE_SINCE_LAST_CORR flop.

After corrupting the user memory, any partial write (e.g., a write with byte selects enabled) may write unknown logic states (X-bits) for any bytes not selected. Similar to the TERN+1F memory modeling option, the TERN+T wrapper 230 or the wrapped memory 212a performs a Read of the tag memory 212b to determine whether the address is valid and if not, modifies the user data (data_in) to unknown bit values (X-bits) and then writes all bytes. If the address is valid, then the memory writes only the selected bytes.

For memory dumps, the TERN+T wrapper 230 or certain emulation runtime logic reads a given tag location and the corresponding key to determine if there is a match, and if there is no match, then the wrapper 230 or other emulation runtime logic outputs an unknown value (X-bit).

For memory loads, the wrapper 230 or other emulation logic reads the key and writes the value to the corresponding address in the tag memory 212b, and generates a signal depositing ‘1’ to, for example, the WRITE_SINCE_LAST_CORR flop.

After detecting a key overflow, the wrapper 230 or the emulation logic raises a fatal error assertion indicating invalid data and/or stops to rewrite to the tag memory 212b.

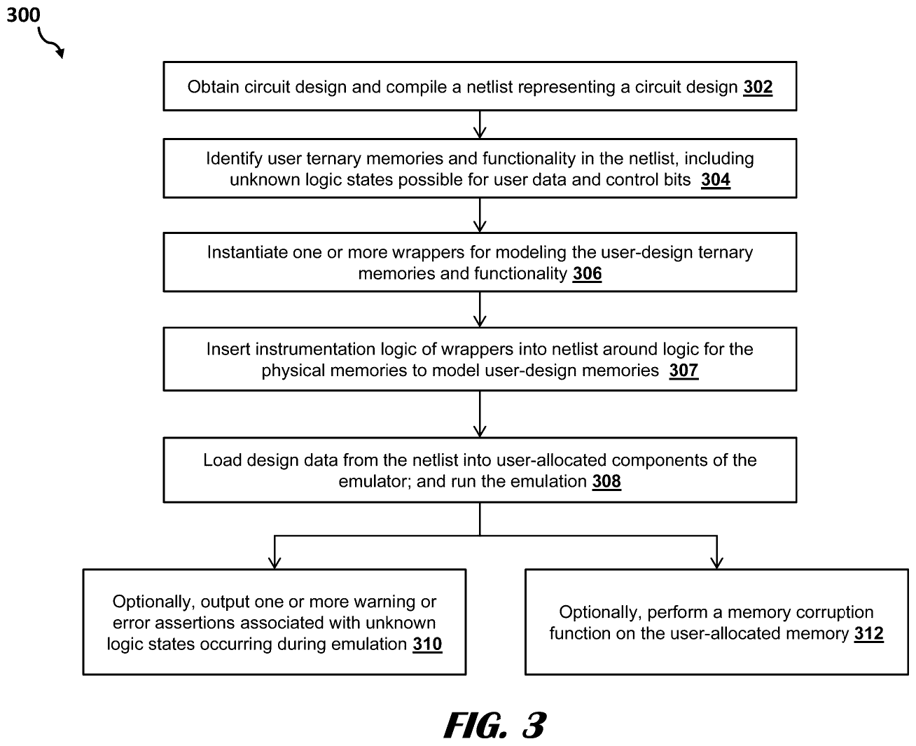

FIG. 3 shows operations of a method 300 for an emulation system having components to emulate and model an IC design that operates with unknown logic states and ternary memory functionality.

In step 302, a compiler obtains and compiles an IC design into one or more design files (e.g., netlist) written in a machine-readable hardware design. The designer's logic design data is in, for example, is in a HDL (e.g., Verilog) and the compiler then complies and synthesizes into the netlist.

In step 304, the compiler identifies or detects instances of four-state modeling functionality or operations occurring in the netlist or other design file. The four-state modeling functionality includes identifiable or detectable attributes, such as instances of unknown logic states or the potential for unknown logic state arising in user data or control bits. The compiler may detect the four-state modeling functionality by executing various preconfigured matching or recognition functions of the compiler software. The sources of unknown values (X) should not be limited to these examples. An unknown value (X) may occur or arise anywhere and may propagate anywhere, although the emulation runs may only perform X-modeling in certain modules of the IC design to minimize costs or time.

In step 306, the compiler instantiates one or more wrappers for the emulator's physical binary memories to perform as user ternary memories for modeling the three logic states relevant to the emulator (0, 1, unknown value X). The compiler references a database containing a library of wrappers or wrapper code for implementing aspects of the ternary memory modeling options (as in TABLE 1).

For instance, during synthesis, the compiler (or other software component) performs a memory synthesis operation that synthesizes the logic and infers memories. The compiler may determine, for example, there is a signal occurring in the Verilog logic that appears multi-dimensional capable of being unknown signal or unknown logic, or the compiler determines the multi-dimensional signal gets written based on an address. The compiler looks, for example, at the code and sees that there is an array (“mem[ ]”) declared and that under some location (“mem[A]”) is written with some data. In this example, the compiler infers that the “mem[ ]” array should represent a memory. The compiler may further determine that there are other places where, based on the address being assigned, part of the user-memory returns that data from an address on the data_out port. For every read or write port on a memory, the compiler generates an entry in the netlist database or other database library, where the memory component and function (read or write) is represented as a primitive, such as a memory port read (MPR) or memory port memory port write (MPW). The memory includes the ports indicated by the address bits, including data inputs, data outputs.

In some embodiments, because the memories can have many ports, several ports may be associated with the same memory (multi-port memory). The compiler and memories associate the ports with memory by tying a synchronization virtual phantom output bit, called SYNC_OUT, from one memory, to the SYNC_IN of another memory, which allows the backend compiler to see that these ports (or other primitives or design features) are implementing the same memory. The other purpose of the SYNC path is for the memories, compiler, or other component of the emulator to maintain awareness of the priority of access during a cycle, allowing components to access (e.g., read, write) a multi-ported memory in the correct order.

To implement ternary memory functionality, the compiler infers a memory and the ports of the memory as before. The conventional synthesis functions would normally generate these MPRs and MPWs primitives. However, when a ternary memory is detected during synthesis, the compiler instead instantiates logic for a netlist representing a ternary wrapper (e.g., TERN wrapper) from the library database. The compiler then, for example, creates primitives or functions (e.g., MPRs, MPWs), and sets appropriate parameters in terms of the number of ports and the width of ports (as reflected in TABLE 1). The logic of the wrapper is merged or injected into the netlist's logic (around the logic of the particular memory) to handle the resolution of what happens with inputs or outputs to each port at the occurrence of unknown values (X-bits).

Additionally or alternatively, in some embodiments, generating and inserting the ternary memory wrapper's logic replaces (rather than merely wraps around) logic for certain operations that normally occur during the memory synthesis. For instance, the handling of ternary-related behaviors, necessary to model X-bits on control bits, should be performed in the logic of the wrapper around the MPR/MPW.

As an example, if a ternary memory is supposed to perform “no write” in the case of an X-bit occurring on an address, then a conventional compiler or synthesis program (e.g., HDL-Ice) would create logic for an appropriate MPW instance for the memory indicated. However, rather than creating the MPW instance through conventional synthesis, a wrapper may substitute for the MPW logic, where the wrapper includes the logic required for the particular memory to model the conditional ternary operation (e.g., if unknown X, then “no write”). The compiler eventually merges (as in step 308) the wrapper logic into the netlist logic or other logical design file.

In step 307, the compiler (or other software component) inserts the instrumentation logic of the wrappers into the netlist, around the netlist logic for the corresponding user ternary memory to be modeled by the physical binary memory of emulator hardware. For example, the compiler identifies or detects, in the netlist for the DUT, certain netlist logic for a user ternary user memory and the compiler schedules a physical binary memory of the emulator hardware to model the user ternary memory. The compiler determines (as in step 304) a set of one or more primitives, parameters, and functions of the detected instance of the user ternary memory, and instantiates (as in step 306) the particular wrapper having instrumentation wrapper logic based on the primitives and parameters. The compiler (or other software component) selects or identifies an available physical binary memory to allocate to the user's emulation run and schedule for modeling the particular user ternary memory, where the selected physical binary memory is scheduled to receive the netlist logic for the particular instance of user ternary memory. The compiler merges the wrapper into the netlist of the DUT, by merging (e.g., replacing, augmenting, appending) the wrapper logic instantiated for the user ternary memory around the netlist logic of the particular physical memory hardware scheduled to receive the netlist logic.

In step 308, the compiler (or other software component) compiles the updated logic of the netlist (or other logical design file) into instruction sets and memory bits or bytes, and loads this design data into scheduled user-allocated hardware components of the emulator. In the current step 308, the updated netlist includes the instrumentation logic as merged into the initial netlist logic of the DUT netlist. The instrumentation logic includes the virtual logic merged with the user's initial DUT netlist, such as wrapper logic of the memory wrappers, and administrative logic for managing various administrative functions of the emulation system, among other types of instrumentation logic. The emulator hardware components then emulate the user-design components according to the portions of the machine instructions of the updated netlist logic loaded into the particular hardware.

Optionally, in step 310, the wrapper logic or the user ternary memory (or other aspect of the emulator) outputs one or more warning signals or error assertions associated with the ternary user memory in response to an unknown logic state (X-bit) occurring at a port of the user ternary memory. The wrapper includes instructions configuring the user memory to perform certain functions (e.g., generate a warning message) when certain conditions arise at a memory port (e.g., unknown logic occurs, key overflow). The wrapper identifies an instance of an unknown logic state (X-bit) occurring (e.g., input or output) at a port of the user ternary memory as an inbound or outbound user content data, and generates the warning signal or error assertion.

Optionally, in step 312, the user ternary memory performs a memory corruption function on the user memory, according to the wrapper. The wrapper performs the memory corruption function in response to an unknown logic state (X-bit) occurring at a port of the user ternary memory, in response to a given condition, or after a given number of corruption events triggering the memory corruption function. In some cases, the wrapper performs the memory corruption function in response to a given user input received as manual input from a user device or user interface.

The memory corruption may also be in response to certain instrumentation logic of the wrapper defining a condition for triggering the memory corruption. For example, with UPF modeling as the user's IC design, a UPF design file or DUT netlist logic defines, for example, power domains of an ASIC, as well as the logical conditions within the user-design components under which a power domain is powered down, and the behavior of the user-design components to model in that power domain when powered-down. It is generally common that memories do not function, and do not retain the memory's state, when powered down. For an emulation to model instances when the power domain is powered down, the instrumentation logic must corrupt the user ternary memory. This is handled by UPF modeling instrumentation logic, which includes wrapper logic of a wrapper in the power domain that controls a CORRUPT_NOW input. In this way, the UPF modeling instrumentation logic initiates the power down, causing the wrapper instrumentation logic to perform the memory corruption.

The various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

Embodiments implemented in computer software may be implemented in software, firmware, middleware, microcode, hardware description languages, or any combination thereof. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, attributes, or memory contents. Information, arguments, attributes, data, etc. may be passed, forwarded, or transmitted via any suitable means including memory sharing, message passing, token passing, network transmission, etc.

The actual software code or specialized control hardware used to implement these systems and methods is not limiting of the invention. Thus, the operation and behavior of the systems and methods were described without reference to the specific software code being understood that software and control hardware can be designed to implement the systems and methods based on the description herein.

When implemented in software, the functions may be stored as one or more instructions or code on a non-transitory computer-readable or processor-readable storage medium. The steps of a method or algorithm disclosed herein may be embodied in a processor-executable software module which may reside on a computer-readable or processor-readable storage medium. A non-transitory computer-readable or processor-readable media includes both computer storage media and tangible storage media that facilitate transfer of a computer program from one place to another. A non-transitory processor-readable storage media may be any available media that may be accessed by a computer. By way of example, and not limitation, such non-transitory processor-readable media may comprise RAM, ROM, EEPROM, CD-ROM or other optical disk storage, magnetic disk storage or other magnetic storage devices, or any other tangible storage medium that may be used to store desired program code in the form of instructions or data structures and that may be accessed by a computer or processor. Disk and disc, as used herein, include compact disc (CD), laser disc, optical disc, digital versatile disc (DVD), floppy disk, and Blu-Ray disc where disks usually reproduce data magnetically, while discs reproduce data optically with lasers. Combinations of the above should also be included within the scope of computer-readable media. Additionally, the operations of a method or algorithm may reside as one or any combination or set of codes and/or instructions on a non-transitory processor-readable medium and/or computer-readable medium, which may be incorporated into a computer program product.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. An emulation system comprising:
emulator hardware for emulating a circuit design, including one or more emulation processors for modeling user design circuits of a netlist for the circuit design, and one or more physical binary memories for modeling user design memories of the netlist; and
a computing processor configured to:
identify, in the user design memories of the netlist, a user ternary memory to be modeled using a physical binary memory; and
instantiate a wrapper for modeling the user ternary memory, the wrapper includes instrumentation logic configured to perform one or more logical transformations of a ternary interface signal to model the user ternary memory, wherein the user ternary memory is modeled using a combination of the instrumentation logic of the wrapper and a portion of the netlist for the physical binary memory.

2. The system according to claim 1, wherein the computing processor is further configured to merge the instrumentation logic of the wrapper with netlist logic of the netlist by including the instrumentation logic of the wrapper around a portion of the netlist logic for the physical binary memory to model the user ternary memory.

3. The system according to claim 1, wherein the computing processor is further configured to determine, based upon the netlist, one or more ternary memory functions to be modeled at the user ternary memory, and
wherein the computing processor instantiates the wrapper according to the one or more ternary memory functions.

4. The system according to claim 3, wherein the user ternary memory is configured to model, according to the instrumentation logic of the wrapper, the one or more user ternary memory functions in response to an unknown logic state occurring at a port or memory location of the user ternary memory being modeled.

5. The system according to claim 1, wherein the user ternary memory is configured to output, according to the instrumentation logic of the wrapper, a warning in response to an unknown logic state occurring at the user ternary memory.

6. The system according to claim 1, wherein a tag bit stored in a tag memory for the user ternary memory being modeled indicates whether a particular memory location in the user ternary memory includes an unknown logic state.

7. The system according to claim 1, wherein the computing processor is further configured to determine one or more wrapper parameters for instantiating the wrapper based upon the netlist, wherein the computing processor instantiates the wrapper according to the one or more wrapper parameters.

8. The system according to claim 7, wherein, when determining the one or more wrapper parameters, the computing processor is further configured to:
identify one or more memory dimensions for at least one of the user ternary memory to be modeled or the physical binary memory, wherein the instrumentation logic of the wrapper is configured to perform the one or more logic transformations according to the one or more memory dimensions.

9. The system according to claim 7, wherein, when determining the one or more wrapper parameters, the computing processor is further configured to:
identify, based upon the netlist, one or more memory ports of the user ternary memory to be modeled, wherein the instrumentation logic of the wrapper is configured to perform the one or more logic transformations according to the one or more memory ports.

10. An emulation system comprising:
emulator hardware for emulating a circuit design that operates with an unknown logic state, including one or more emulation processors for modeling user design circuits of a netlist for the circuit design, and a plurality of physical binary memories for modeling user design memories of the netlist; and
a computing processor configured to:
identify, in the user design memories of the netlist, a user ternary memory to be modeled using a physical binary memory; and
instantiate a wrapper for modeling the user ternary memory, the wrapper includes instrumentation logic configured to perform one or more logical transformations of a ternary interface signal to model the user ternary memory, and to perform a memory corruption function, wherein the user ternary memory is modeled using a combination of the instrumentation logic of the wrapper and a portion of the netlist for the physical binary memory.

11. The system according to claim 10, wherein the emulation hardware includes a tag flop associated with the memory location of the user ternary memory, and wherein the tag flop indicates that the memory location of the user ternary memory is valid when the tag flop is asserted; and
wherein the instrumentation logic of one or more wrappers determines whether the memory location is valid based upon the flop device.

12. The system according to claim 11, wherein, and when executing the memory corruption function, the instrumentation logic is configured to de-assert the flop device in response to an unknown logic state occurring in memory content or a target address during a memory-read function.

13. The system according to claim 11, wherein, and when executing the memory corruption function, the instrumentation logic is configured to de-assert the flop device in response to an unknown logic state occurring during a memory-write function.

14. The system according to claim 11, wherein, and when executing the memory corruption function, the instrumentation logic is configured to:
detect a condition involving unknown states; and
de-assert a plurality of flop devices corresponding to a plurality of memory locations of a plurality of user ternary memories in response to the condition.

15. The system according to claim 10, wherein the plurality of physical binary memories of the emulator hardware include a tag memory configured to store one or more tags associated with one or more memory locations in one or more user ternary memories, wherein a value of a tag corresponds to the value of a key applied to the memory location; and
wherein the instrumentation logic of one or more wrappers is further configured to determine whether the memory location is valid based upon the tag associated with the memory location in the user ternary memory.

16. The system according to claim 15, wherein the instrumentation logic of the wrapper is configured to apply the value of the key on the memory location during a write function, and update the value of the tag according to the value of the key.

17. The system according to claim 15, wherein the instrumentation logic of the wrapper is configured to output a key overflow warning in response to detecting a key-value overflow for the memory location.

18. The system according to claim 15, wherein, when executing the memory corruption function, the instrumentation logic of the wrapper is configured to:
update the value of the key corresponding to the tag associated with the memory location in response to an unknown logic state occurring in memory content or a target address during a memory-read function.

19. The system according to claim 15, wherein, when executing the memory corruption function, the instrumentation logic of the wrapper is configured to:
update the value of the key corresponding to the tag associated with the memory location in response to an unknown logic state occurring during a memory-write function.

20. The system according to claim 15, wherein, when executing the memory corruption function, the instrumentation logic of the wrapper is configured to:
detect a condition involving unknown states; and
update each value of one or more keys corresponding to one or more tags associated with one or more memory locations in response to the condition.
